(19) United States
(12) Patent Application Publication
(10) Pub. No.: US 2024/0128382 A1
(43) Pub. Date: Apr. 18, 2024

(54) A PHOTOVOLTAIC MODULE HAVING A DESIRED APPEARANCE

(71) Applicant: ALPHA SOLAR TECHNOLOGIES PTY LTD, Kewdale, Western Australia (AU)

(72) Inventor: Kamal ALAMEH, Rivervale, Western Australia (AU)

(21) Appl. No.: 18/277,446

(22) PCT Filed: Feb. 18, 2022
(86) PCT No.: PCT/AU2022/050120

§ 371 Date: Aug. 16, 2023

(30) Foreign Application Priority Data
Mar. 10, 2021 (AU) 2021900691

(51) Int. Cl. H01L 31/0216; H01L 31/18

(52) U.S. Cl. CPC H01L 31/02167; H01L 31/18

(57) ABSTRACT

The present disclosure provides a photovoltaic module having a desired appearance. The module comprises at least one solar cell having black or dark surface portions. The module further comprises a material layer positioned over the black or dark surface portions. The material layer has material portions being lighter in colour or appearance than the black or dark surface portions. The material portions have a transmissivity for visible light dependent on a composition and/or thickness of the material portions. The material layer is at least largely transmissive for light at areas between the material portions. A visible layer is positioned over the material layer and includes at least one of: an image, a pattern or a colour. The thickness, composition and/or lateral coverage of the material portions of the material layer are selected dependent on a desired contrast and/or a darkness, brightness or colour of features of the desired appearance of the photovoltaic module.

### FIELD OF THE INVENTION

The present disclosure relates to a photovoltaic module having a desired appearance and relates particularly, though not exclusively, to a photovoltaic module having a visible layer including an image or visible feature.

### BACKGROUND OF THE INVENTION

Photovoltaic modules convert incident solar light into electricity and are typically positioned on roof spaces of buildings, on side walls of buildings or at various other places (such as on traffic islands to provide electricity for traffic signs and the like). Photovoltaic modules generally have surface portions that appear black or dark as active surfaces of solar cells, usually positioned below protective transparent panels, have such black or dark appearance.

It has previously been proposed to print images or structures on such photovoltaic modules in order to improve the visual appearance of the photovoltaic modules. However, such prints or structures reduce the transmissivity of the solar lights. As less solar light can be received by the solar cells to generate electricity, the electrical output of the photovoltaic modules is also reduced.

The present disclosure provides technological advancement.

### SUMMARY OF THE INVENTION

The present invention provides in a first aspect a photovoltaic module having a desired appearance, the module comprising:
at least one solar cell having black or dark surface portions;
a material layer positioned over the black or dark surface portions of the at least one solar cell, the material layer having material portions being lighter in colour or appearance than the black or dark surface portions of the at least one solar cell, the material portions having a transmissivity for visible light dependent on a composition and/or thickness of the material portions, the material layer being at least largely transmissive for light at areas between the material portions; and
a visible layer positioned over the material layer and including at least one of: an image, a pattern or a colour; wherein the thickness, composition and/or lateral coverage of the material portions of the material layer are selected dependent on a desired contrast and/or a darkness, brightness or colour of features of the desired appearance of the photovoltaic module.

The at least one solar cell may be provided in the form of a photovoltaic module, such as a conventional photovoltaic module.

The material layer may comprise a plurality of islands, which may be provided in any suitable form or size, and in one specific embodiment, the material portions are dots, such as printed dots having a regular or irregular shape. The dots may be sufficiently small such that the dots are invisible to the naked eye. The dots, which may form an array, may have any suitable colour that is lighter than the black or dark appearance of the black or dark surface portions of the at least one solar cell, but in one specific embodiment, the dots have a white appearance when the dots are sufficiently thick and have a suitable composition such that they are at least largely not transmissive for visible light. The dots may be formed by a printing process, such as digital printing.

The dots may have a local thickness dependent on desired contrast and/or a darkness or brightness of features of the desired appearance of the photovoltaic module. The thickness of the dots may vary within the material layer. In one specific embodiment of the present invention, at least some of the dots are sufficiently thin such that they have a have transmissivity for visible light which depends on the thickness of the dots. For example, the dots may have, dependent on a desired local transmissivity, a thickness in the range of 0-10 μm or 0-5 μm. When the dots have a thickness greater than a few mm, such as greater than 5 μm the dots block locally at least the majority of incident visible light. However, when the thickness of the dots is between 0 and 5 μm, the dots have a grey or even black or dark appearance (for nearly 0 μm thickness) as the dots are positioned over the black or dark surface portions of the at least one solar cell. The dots may be formed using a digital printing process. A desired thickness variation of the dots within the material layer may be achieved using a sequence of printing procedures. In a successive printing procedure, a selection of dots may be printed over dots printed in a previous procedure resulting in an increase in thickness. A total (accumulated) printed thickness of each dot depends on a selection of dots printed in each printing procedure in the sequence of printing procedures.

Alternatively or additionally, the dots may have a composition dependent on desired contrast and/or a darkness or brightness of features of the desired appearance of the photovoltaic module. In this case, the dots may have a transmissivity dependent on the composition of the dots. For example, the dots may comprise non-transparent ink, such as white ink, and a transparent ink. The dots may have, dependent on a desired local transmissivity, a composition including 0-20%, 20-40%, 40-60%, 60-80% or 80-100% transparent ink with the remainder being a non-transparent ink whereby a transmissivity of the dots depends on the composition of the dots. The dots may have a thickness between 0-5 μm or thicker. By varying the composition of the dots, a degree of blackness (or darkness) of the dots can be controlled as the dots are positioned over the black or dark surface portions of the at least one solar cell.

The present invention provides the advantage that it is not necessarily required to print black or dark features when the image is formed within the visible layer over the material layer, as it is possible to provide the dots with a selected thickness or composition variation within the material layer such that the black or dark features are visible with a desired contrast. In one specific embodiment, the visible layer includes a printed image formed within the visible layer without the use of back colour, even though features of the image as visualised from out the photovoltaic module appear black or dark. For example, the image may be printed using the colours cyan, magenta and yellow only.

Black colour when printed has the most detrimental impact on the transmissivity of visible light and consequently on the conversion efficiency of the photovoltaic module. As in an embodiment of the present invention the use of black colour for forming the image is avoided, the present invention, in accordance with embodiments, provides the advantage that the photovoltaic module has an increased conversion efficiency.

Further, the material layer may provide a coverage (such as a diameter of the dots and distance between the dots) dependent on a desired contrast and/or a darkness or brightness of features of the desired appearance of the photovoltaic module. As areas between the dots are at least largely transmissive for visible light, the areas between the dots positioned over the black or dark portions of the at least one solar cell appear black or dark. It is consequently possible to influence a degree of darkness by varying a diameter of the dots and/or an extension of gaps between adjacent dots. As the areas between the dots have a black or dark appearance, smaller dots and larger gaps between the dots result in a darker appearance.

In one embodiment, the dots have a diameter of 50 μm-200 μm, such as in the order of 100 μm, and gaps between adjacent dots have an extension of 20-40 μm, 40-60 μm, 60-80 μm and 80-100 μm such as 30 μm.

In one specific embodiment, the thickness and composition of the dots of the material layer and properties of the image of the visible layer are selected such that at least the majority or all areas of visible layer and the material layer have a transmissivity for visible light greater than zero. As mentioned above, the dots have in one embodiment a white appearance when they are sufficient thick and have a suitable composition. However, when the dots have a thickness and composition such that they appear white, the dots block a significant portion of light transmission. The inventor has observed that good and acceptable contrasts in the image can already be achieved if even in lighter coloured areas of the image the transmissivity of the dots is increased. For example, this may be achieved by reducing the thickness of the dots to 70% or less, 50% or less, 30% or less, 20% or less even to 10% less of the minimal thickness at which the dots would block transmission of visible light through the dots by more than 90%. Alternatively, a composition of the dots may be changed by increasing a percentage amount of a transparent component, such as a transparent ink, for forming the dots to 30% or more, 50% or more, 70% or more, 80% or more or even 90% or more. The inventor has observed that even if the transmissivity is increased to 85% of a transmissivity at which the dots would result in a highest quality image with highest contrast, a sufficient contrast is still visible. As the transmissivity is increased, the conversion efficiency of the photovoltaic module even further.

In one embodiment, the dots have a thickness ranging from 0 μm to 5 μm. The dots may for example be formed using, for example, UV-flatbed inkjet or ceramic digital printing. The at least one solar cell may be of any suitable type, but, in one specific embodiment, is a cadmium telluride (CdTe)-based solar cell.

The visible layer may be a first visible layer positioned over a first major surface of the at least one solar cell. Further, the photovoltaic module may comprise a second visible layer including at least one of: a colour, an image and a pattern. The second visible layer may be positioned over a second major surface of the at least one solar cell and which is opposite the first major surface such that the first and second visible layers are visible at opposite sides of the at least one solar cell.

A layer of transparent ink or varnish may be positioned over the material layer to substantially equalise height differences of the dots and substantially fill gaps between adjacent dots.

The present invention provides in a second aspect a method of forming a photovoltaic module having a desired appearance, the method comprising the steps of:
providing at least one solar cell having black or dark surface portions;
   forming a material layer over the black or dark surface portions of the at least one solar cell, the material layer having material portions being lighter in colour or appearance than the black or dark surface portions of the at least one solar cell, the material portions having a transmissivity for visible light depending on a thickness and/or composition of the material portions, the material layer being at least largely transmissive for light at areas between the material portions; and
   forming a visible layer, the visible layer including at least one of: an image, a pattern or a colour;
   wherein the material layer is positioned between the black or dark surface portions of the at least one solar cell and the visible layer, and wherein forming the material layer comprises selecting the thickness, composition and/or lateral coverage of the material portions of the material layer dependent on a desired contrast and/or a darkness, brightness or colour of features of the desired appearance of the photovoltaic module.

The step of forming the material layer and/or forming the visible layer may comprise digital printing, such as digital UV printing or digital ceramic printing.

The at least one solar cell may be provided in the form of a photovoltaic module, such as a conventional photovoltaic module.

The material portions of the material layer may be dots. In one embodiment, the dots have a diameter of 50 μm-200 μm, such as in the order of 100 μm, and gaps between adjacent dots have an extension of 20-40 μm, 40-60 μm, 60-80 μm and 80-100 μm such as 30 μm. The dots may have a thickness in the range of 0-10 μm or 0-5 μm.

Forming the material layer may comprise selecting a desired thickness variation of the dots within the material layer. Further, forming the material layer may comprise a sequence of printing procedures wherein a selection of dots may be printed over dots printed in a previous procedure resulting in an increase in thickness. The method may further comprise selecting for each printing sequence locations at which dots will be printed. A total (accumulated) printed thickness of each dot depends on a selection of dots printed in each printing procedure in the sequence of printing procedures. In addition, the method may comprise applying a layer of transparent ink or varnish in a manner such that the transparent ink or varnish fills gaps between adjacent dots and substantially equalises height differences arising from dots having different thicknesses.

Alternatively or additionally, forming the material layer may comprise selecting a composition of the dots and/or a composition variation of the dots within the material layer. In this case the dots may have a transmissivity dependent on the composition of the dots. The dots may be formed using a composition of ink transmissive for visible light and ink not transmissive for visible light. Selecting the composition may comprise selecting a ratio of ink or varnish transmissive for visible light and ink not transmissive for visible light. The method may further comprise applying a layer of the transparent ink or varnish in a manner such that the transparent ink or clear varnish fills gaps between adjacent dots.

In one specific embodiment, the visible layer may be formed on the surface of a transparent panel, such as a glass panel and the step of forming the material layer may comprise forming the material layer directly or indirectly on the visible layer. In a variation of this embodiment a transparent adhesive layer, such as transparent conductive indium tin oxide (ITO), may be positioned on the glass panel, the visible layer may be formed on the adhesive layer and the material layer may be formed on the visible layer.

Further, the method may comprise forming a solar cell structure over the formed material layer. The method may further comprise positioning a glass pane over the formed solar cell structure.

In an alternative embodiment the method comprises providing a solar cell structure and forming the material layer directly or indirectly on a surface of the solar cell structure. The method may further comprise forming the visible layer directly or indirectly on the formed material layer and positioning a glass pane over the formed visible layer.

The invention will be more fully understood from the following description of specific embodiments of the invention. The description is provided with reference to the accompanying drawings.

### BRIEF DESCRIPTION OF THE DRAWINGS

FIGS. 1 and 2 are schematic cross-sectional representations of a photovoltaics module having a desired appearance in accordance with an embodiment of the present invention;

FIG. 2 is a schematic top-views of printed dots;

FIG. 4 is a graph illustrating normalised transmission power as a function of normalised thickness;

FIG. 5 illustrates measured transmission of light as a function of printed colour;

FIG. 6 is a schematic cross-sectional representation of printed dots in accordance with an embodiment of the present invention;

FIGS. 7 and 8 are schematic cross-sectional representations of photovoltaic modules having a desired appearance in accordance with an embodiment of the present invention;

FIG. 9 is a flow chart illustrating a method of forming a photovoltaic module having a desired appearance in accordance with an embodiment of the present invention; and

FIGS. 10 to 12 illustrate embodiments of the method illustrated with reference to FIG. 9.

### DETAILED DESCRIPTION OF EMBODIMENTS

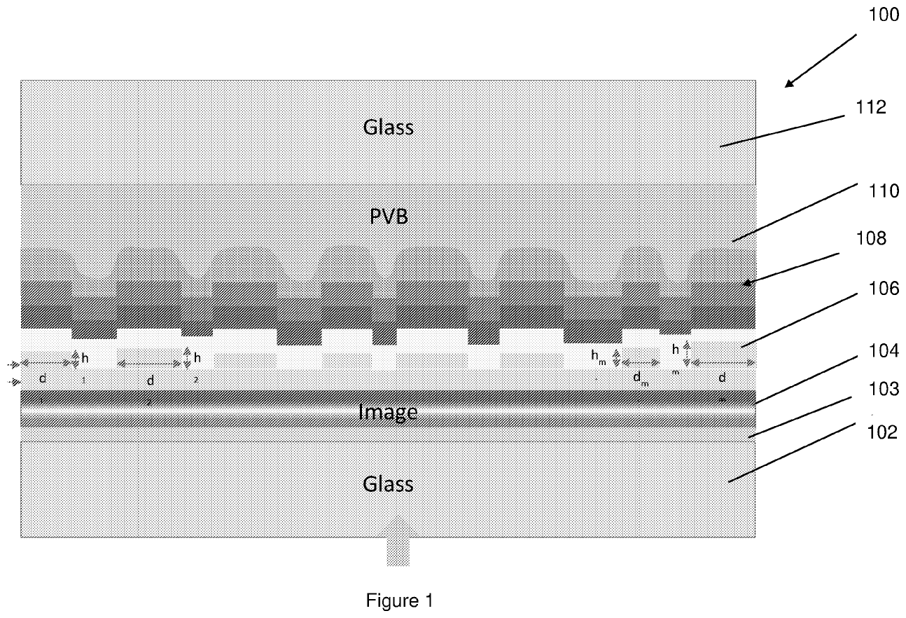

Referring initially to FIG. 1, a photovoltaic module 100 having a desired appearance in accordance with an embodiment is now described. The photovoltaic module 100 comprises a glass panel 102 over which a transparent adhesive layer 103, such as transparent conductive indium tin oxide (ITO) and a visible layer 104 and a material layer 106 are positioned. The visible layer 104 includes an image, colour or pattern. The material layer 106 comprises a plurality of dots having selected thickness (typically in the order of 0-5 μm) and a diameter of typically 10-200 μm. The dots are white (when sufficient thick) and are typically sufficiently small such that the dots are invisible to the naked eye.

The visible layer 104 comprises in this embodiment an image printed over the dots of the material layer 106. The resolution of the image is determined by the density and distribution of the dots of the material layer. The resolution may range from 50-5000 dots per inch. The material layer 106 and the visible layer 104 will be described in further detail below. The photovoltaic module 100 further comprises a plurality of layers 108, which form a solar cell structure and may comprise (i) a transparent electrode layer, such as Indium tin oxide (ITO), (b) an n-type semiconductor layer, such as Cadmium sulfide (CdS), (iii) a p-type semiconductor layer, such as Cadmium Telluride (CdTe) and (iv) a reflective electrode, such as aluminium. The layers 108 form in this embodiment a conventional solar cell structure, which is well known and will not be described in further detail herein. A layer of polyvinyl butyral (PVB) is positioned over the solar cell layers 108, which is used to adhere the resultant structure to glass panel 112.

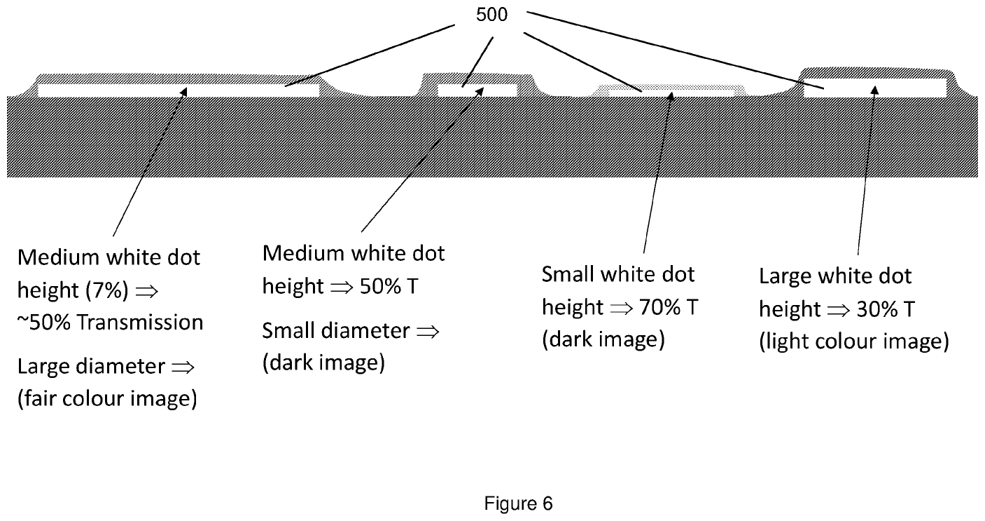

In an alternative embodiment the visible layer 104 and material layer 106 are printed on a front glass panel of a conventional photovoltaic module using a PVB sheet (not shown). This embodiment will be described in detail further below with reference to FIG. 6.

Solar cells and photovoltaic modules have a black or dark appearance (active surface). As mentioned above, the dots of the material layer 16 are of white colour when sufficiently thick, but appear of a darker colour (ranging from grey to black) when the thickness of the dots decreases from 5 μm to 0 μm because they are positioned over the black or dark areas of the solar cell.

Alternatively or additionally, the dots have a transmissivity dependent on the composition of the dots. The dots are in this case formed using a composition of ink transmissive for visible light (such as, Heat Resistant Clear Lacquer, MoTip, which is heat resistant to 800° C., or, transparent glass-ceramic inks made through the annealing of individual or a composition of metal oxide particles, such as Al2O3 or SiO2) and ink not transmissive for visible light. A ratio of ink transmissive for visible light and ink not transmissive for visible light is selected in order to achieve a desired degree of blackness or darkness.

Further, not only the thickness and composition of the dots, but also the diameter of the dots influences a contrast and/or a darkness or brightness of features of the desired appearance of the photovoltaic module. Areas between the dots are transmissive for visible light and consequently appear black or dark (the colour of the conventional photovoltaic module). The visible layer 104 may consequently not necessarily include black or dark features when an image is formed within the visible layer over the material layer, as it is possible to provide the dots with a selected thickness and diameter variation within the material layer such that the black or dark features are visible.

The visible layer 104 includes in this embodiment a printed image formed within the visible layer 104 without the use of back colour, even though features of the image as viewed from out the photovoltaic module 100 appear black or dark. The image is printed using cyan, magenta and yellow only. As no black ink is used for printing, a detrimental impact on the transmissivity of visible light through the visible layer can be reduced and consequently on the conversion efficiency of the photovoltaic module. Both the dots of the material layer 106 and the visible layer 104 may be formed using a digital printing process, such as digital UV printing or digital ceramic printing.

Further, the inventor has observed that good and acceptable contrasts in the image can already be achieved if even in lighter coloured areas of the image the thickness of the dots is reduced or transmissivity of the dots is increased by selecting a suitable composition of the dots. In this embodiment, the transmissivity of the dots is increased by 85% compared which the dots would block transmission through the dots. This can be achieved by reducing the thickness of the dots to 15% of the minimal thickness at which the dots would block transmission through the dots. Alternatively, the transmissivity of the dots is increased by 85% by selecting a suitable composition of the dots (increase amount of transparent ink component accordingly). The increase in transmissivity improves the conversion efficiency of the photovoltaic module. It will be appreciated by a person skilled in the art that, in a variation of the described embodiment, the dots may have any other suitable thickness or composition.

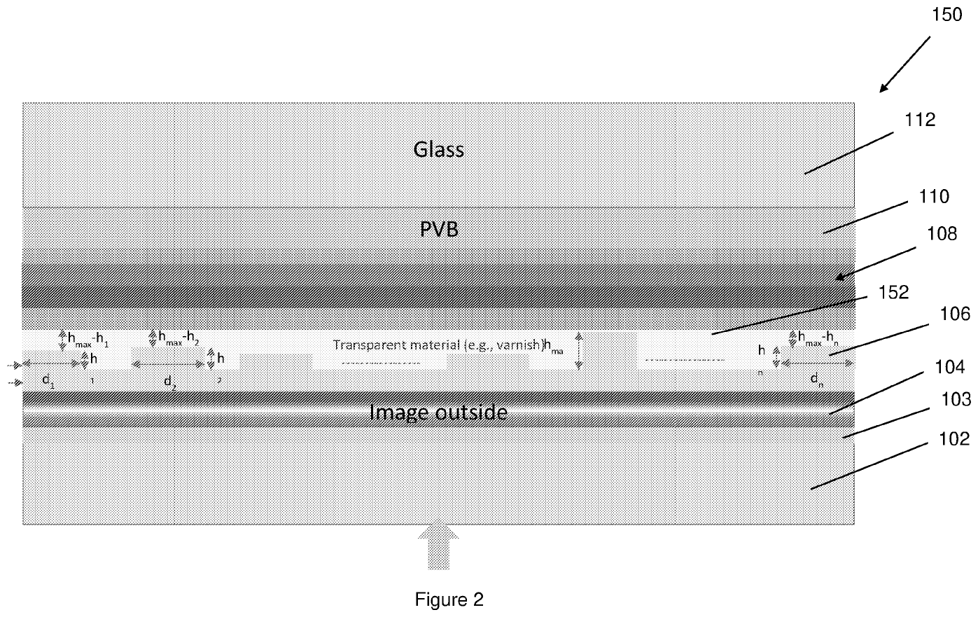

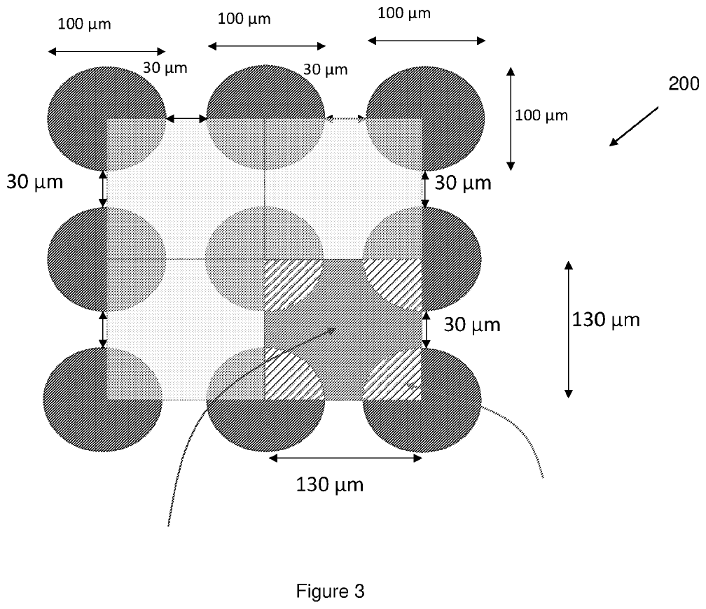

FIG. 2 shows a further photovoltaic module in accordance with an embodiment of the present invention. The shown photovoltaic module 150 is related to the photovoltaic module 100 illustrated with reference to FIG. 1 and like components are given like reference numerals. The photovoltaic module 150 comprises a layer of transparent ink or heat-resistant clear varnish (or lacquer) 152, which may for example be composed of a combination of chemicals, such as, acetone, propane, butane, isobutane, 2-methoxy-1-methylethyl acetate, n-butyl acetate, butan-1-ol and xylene. The transparent ink or heat-resistant clear varnish fills gaps between adjacent dots and equalised height differences between the dots forming a planar surface on which the solar cell structure 108 is formed.

Referring now to FIGS. 3-6, the dots of the material layer 106 and the visible layer 104 are now described in further detail. In this embodiment the dots 200 have a cylindrical shape and form an array. The dots are formed using a digital printing process using digital inkjet printer. The dots are white in colour (when sufficiently thick) and have a thickness selected dependent on desired contrast and/or a darkness or brightness of features of the desired appearance of the photovoltaic module. FIG. 3 illustrates a small selection of the dots of the material layer 106 and the dots happen to have identical diameters within the small selected area. In the illustrated example the dots have a diameter of 100 μm and a gap between the dots is 30 μm.

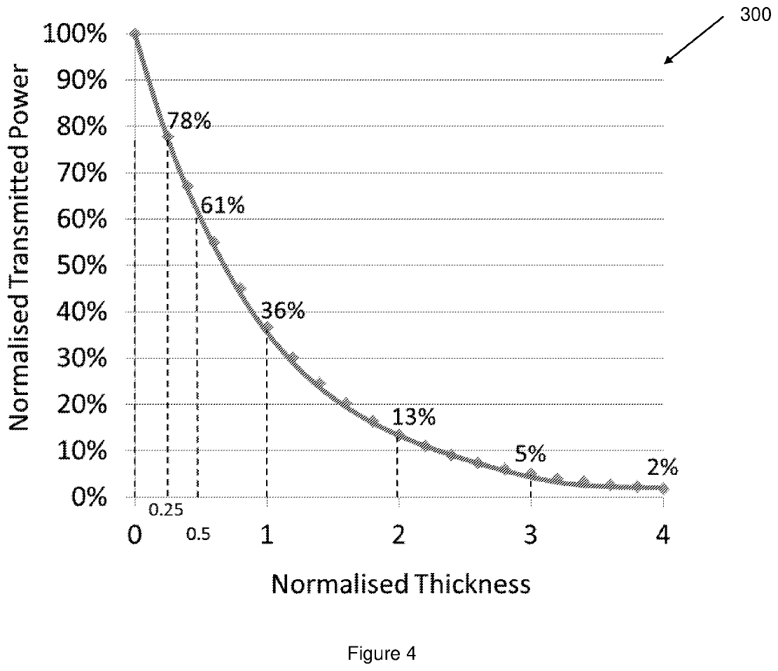

FIG. 4 is a graph of normalised transmissivity of visible light as a function of normalised thickness for the dots. As can be seen the transmissivity decreases exponentially with thickness of the dots, reaches 2% at a thickness of 4 μm and nearly zero at thicknesses over 5 μm.

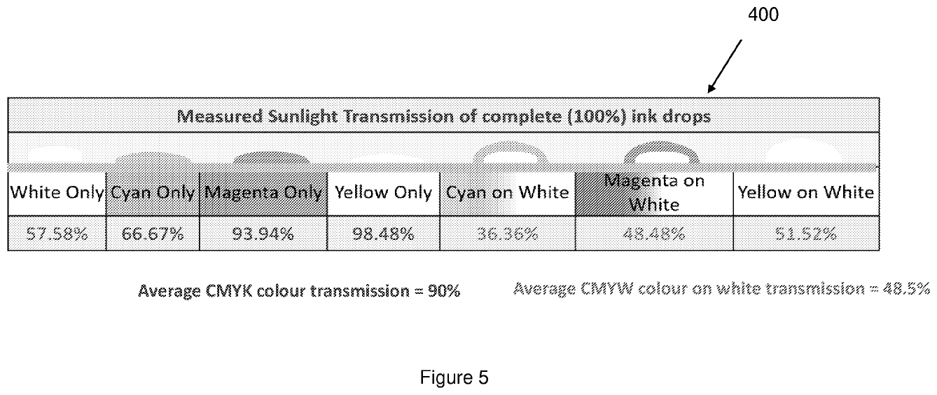

FIG. 5 illustrates measured transmissivity of printed colour magenta, cyan, yellow and white (thickness approximately 5 μm) on glass or white dots (thickness approximately 5 μm) on glass. The white dots have a transmissivity for visible light of 57.58%. The printed colour on glass has an average transmissivity of 90% and the printed colour on white dots has an average transmissivity of 48.5%. Assuming the white dots have a size and distribution as illustrated in FIG. 3 with colour also printed within areas between the dots (and consequently al average transmissivity of 90% between the dots), the total average transmissivity for the dot distribution shown in FIG. 2 is approximately 70.5%.

FIG. 6 is a cross-sectional representation of a portion of a photovoltaic module in accordance with an embodiment of the present invention. FIG. 6 shows a portion of the material layer in the form of dots 500 and a portion of the visible layer in the form of printed colour on the dots 500. The illustrated dots 500 have a range of diameters, thicknesses and compositions as determined by the desired appearance of the photovoltaic module. As discussed above, the material layer with the dots 500 is positioned over the dark or black regions of a conventional photovoltaic module and consequently the diameter, thickness and composition (which determines the transmissivity of the dots for visible light) determines darkness, brightness and contrast of features (for example of an image) as visible within the visible layer.

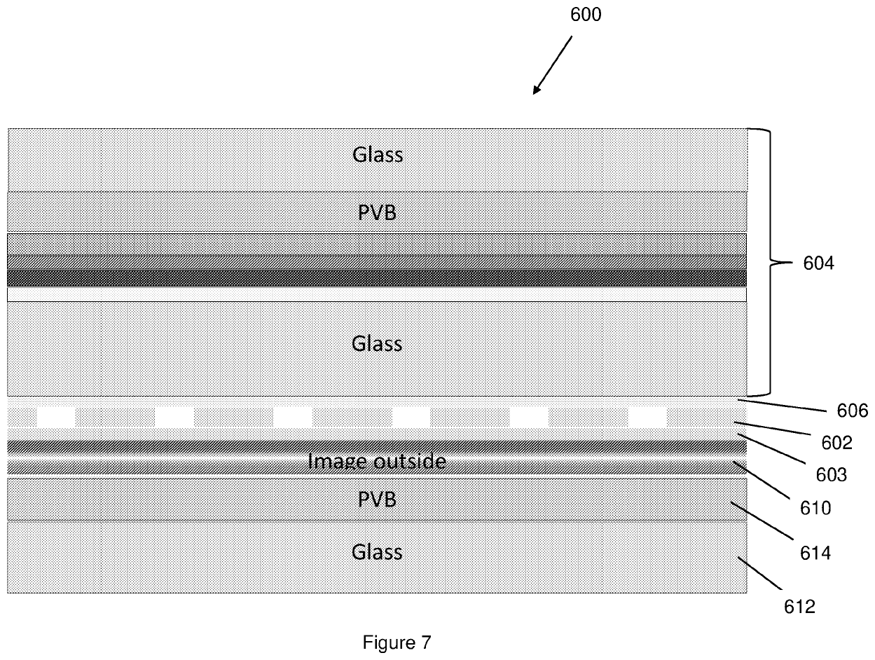

Referring now to FIG. 7, there is shown a photovoltaic module 600 in accordance with an embodiment of the present invention. The photovoltaic module 600 comprises a material layer 602 formed on a transparent outer panel of a conventional photovoltaic module 604, optionally directly on a thin adhesive layer 606. The material layer 602 may alternatively be positioned on a thin layer 603 that is largely transparent for visible light. Visible layer 610 is formed over the material layer 608. The visible layer 610 and the material layer 608 are analogous to the visible layer 104 and material layer 106 described above with reference to FIGS. 1 to 5. As described above, the thickness, composition and coverage of the white dots of the material layer 602 are selected to achieve a desired visual appearance of the photovoltaic module 600. A glass panel 612 is then adhered to the resultant structure using a PVB layer 614.

A person skilled in the art will appreciate that conventional photovoltaic modules are well known in the art and usually have outer panels formed from a suitable transparent material, such as glass or a polymeric material. In this embodiment the photovoltaic module 604 comprises CdTe-based solar cells.

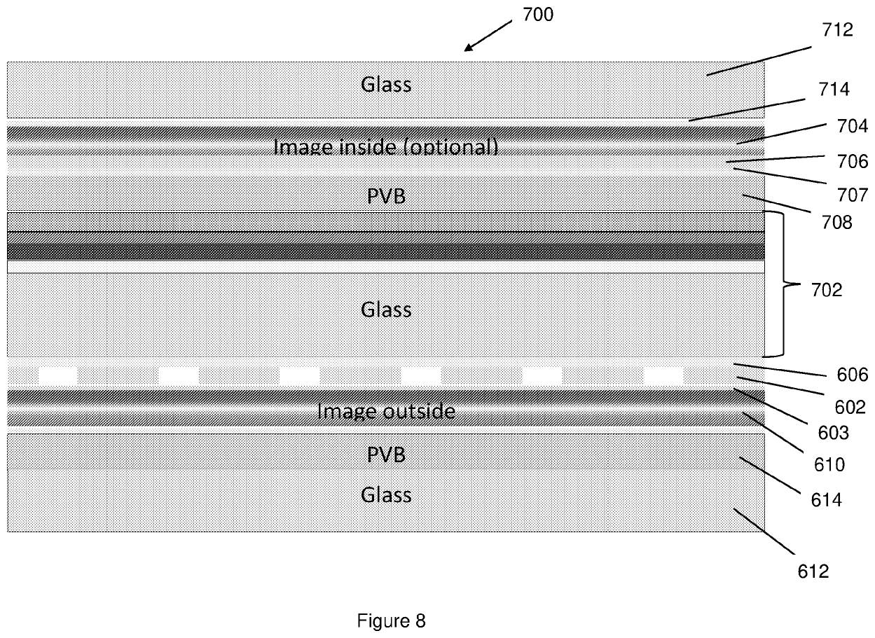

Referring now to FIG. 8, there is shown a photovoltaic module 600 in accordance with an embodiment of the present invention. The photovoltaic module 700 is related to the photovoltaic module 600 illustrated above with reference to FIG. 6 and like components are given like reference numerals. The photovoltaic module 700 includes a conventional solar cell 702 (in this example CdTe-based) and a further visible layer 704, which also includes an image colour or pattern visible form a rear side of the photovoltaic module 700. In this embodiment the visible layer 704 is positioned on a thin white layer 706, which in turn is coupled to the solar cell 702 via a protective layer 707 and a PVB layer 78. The visible layer 704 is also coupled to an outer glass panel 712 via an adhesive layer 714.

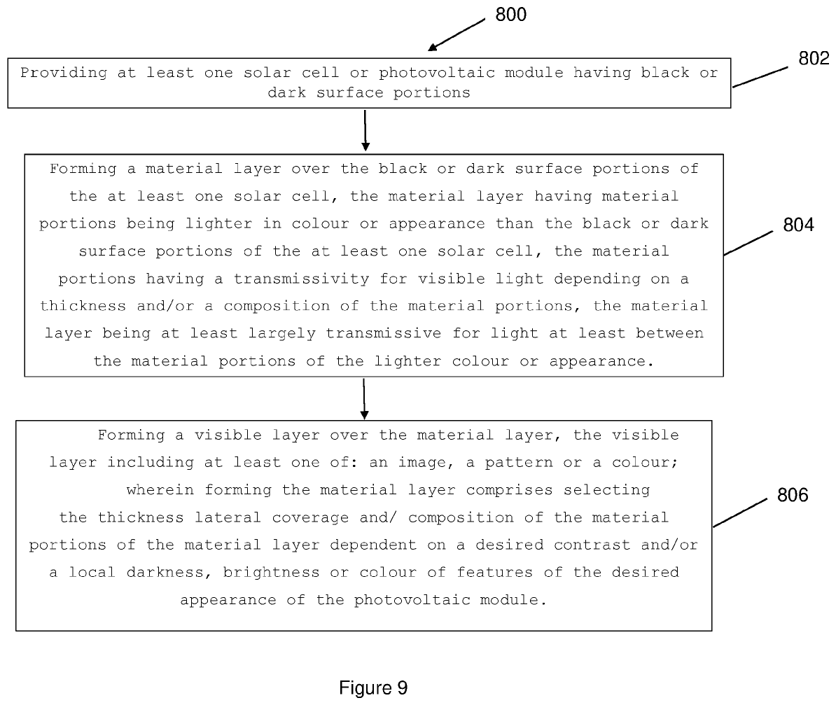

Referring now to FIG. 9, a method of forming a photovoltaic module having a desired appearance in accordance with a specific embodiment of the present invention is now described. The method 800 comprises step 802 of providing a solar cell or photovoltaic module having black or dark surface portions. In this embodiment step 802 comprises providing a conventional photovoltaic module having a plurality of CdTe-based solar cells.

The method 800 further comprises step 804 of forming a material layer over the black or dark surface portions of the solar cell. The material layer has material portions being lighter in colour or appearance than the black or dark surface portions of the solar cell and has a transmissivity for visible light depending on a thickness of the material portions. The material layer is largely transmissive for light between the material portions of the lighter colour or appearance.

In addition, method 800 comprises step 806 of forming a visible layer over the material layer. The visible layer includes in this embodiment an image, but may alternatively also include a pattern or a colour. Forming the material layer comprises selecting the thickness and/or lateral coverage of the material portions of the material layer dependent on a desired contrast and/or a darkness, brightness or colour of features of the desired appearance of the photovoltaic module.

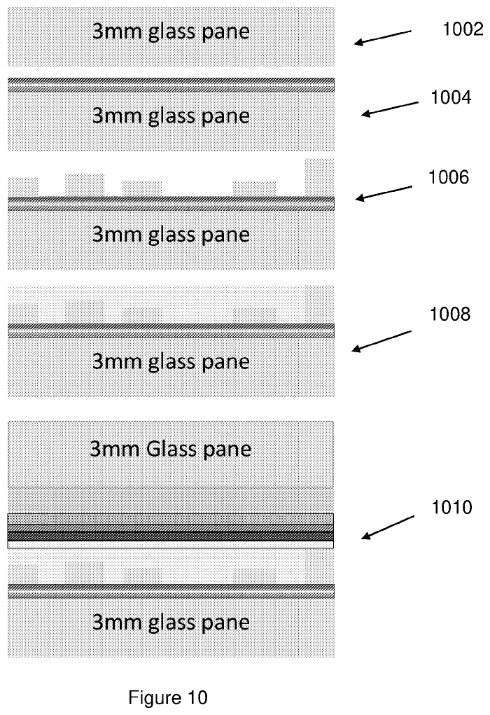

An embodiment of the method 800 will now be described more specifically with reference to FIG. 10. Initially a glass pane is provided (step 1002). In this example the glass pane has a thickness of 3 mm. A visible layer including an image is then formed on the glass pane (step 1004). The visible layer is analogous the visible layer 610 discussed with reference to FIG. 6. A material layer is then formed over the visible layer (step 1006). The material layer is formed using a digital printing process, such as digital UV printing or digital ceramic printing. The material layer comprises dots having thickness varied to achieve a desired transmissivity. This is achieved using a sequence of digital printing procedures. In each subsequent printing procedure of the sequence a selection of dots may be printed over dots printed in previous procedures. A thickness variation can be achieved if not all dots are printed in each sequence and the accumulated thickness of each dot consequently depends on a selection of dots printed in each sequence. Step 1008 then applies a layer of heat-resistant transparent ink or varnish (or lacquer) to fill gaps between dots and to equalise height differences between adjacent dots. The transparent ink or varnish may for example be composed of a combination of chemicals, such as, acetone, propane, butane, isobutane, 2-methoxy-1-methylethyl acetate, n-butyl acetate, butan-1-ol and xylene. Thereafter a conventional thin film solar cell structure is formed either directly or indirectly on the material layer and a glass pane (thickness 3 mm) is then attached to the resultant structure using a layer of PVB (step 1010). A person skilled in the art will appreciated that the formation of such a conventional thin film solar cell structure is well known and will not be described in further detail herein.

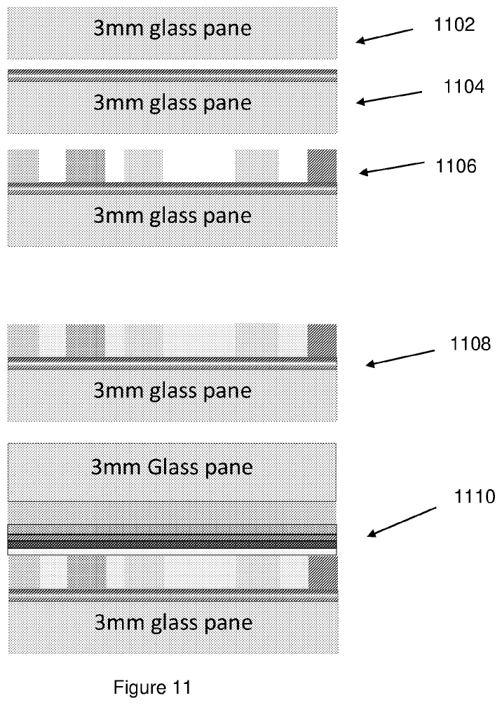

Referring now to FIG. 11, another embodiment of the method 800 will now be described. Initially a glass pane having a thickness of 3 mm is provided (step 1102). A visible layer including an image is then formed on the glass pane (step 1104). The visible layer is analogous the visible layer 610 discussed with reference to FIG. 6. A material layer is then formed over the visible layer (step 1106). In this embodiment the composition of the dots is varied using the digital printing process. In this case the dots are formed using a composition of ink or varnish transmissive for visible light and ink not transmissive for visible light. Forming the dots then comprises selecting a ratio of ink or varnish transmissive for visible light and ink not transmissive for visible light. Step 1008 then applies a layer of heat-resistant transparent ink or varnish (or lacquer) to fill gaps between dots and to equalise height differences between adjacent dots. The transparent ink or varnish (or lacquer) may for example be composed of a combination of chemicals, such as, acetone, propane, butane, isobutane, 2-methoxy-1-methylethyl acetate, n-butyl acetate, butan-1-ol and xylene. Similar to the embodiment illustrated with reference to FIG. 10, a conventional thin film solar cell structure is formed either directly on the material layer (step 1010). A further glass panel (also of 3 mm thickness in this example) is then adhered to the formed structure using the PVB sheet.

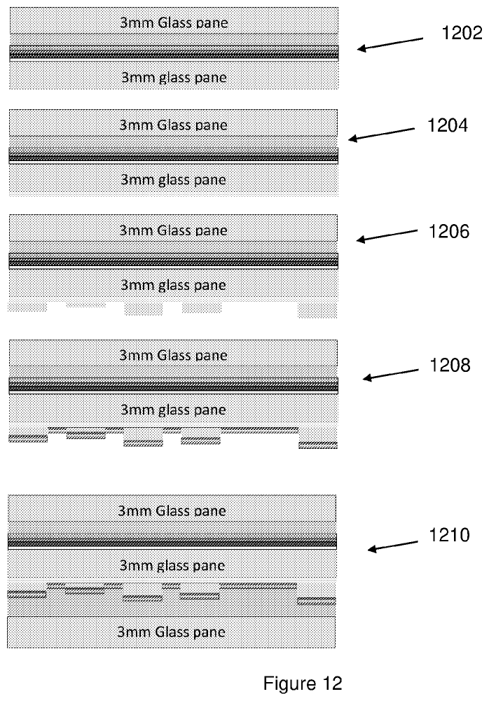

Referring now to FIG. 12 a further embodiment of the method 800 will now be described. In this embodiment the method comprises the initial step 1202 of providing a conventional solar cell module in which the solar cells are sandwiched between glass panes (in this embodiment each glass pane has a thickness of 3 mm). Step 1204 comprises forming an adhesive layer on one of the glass panes. Step 1206 comprises forming a material layer on the adhesive layer. The material layer is formed using a digital printing process and comprises dots having thickness varied to achieve a desired transmissivity. As described above with reference to FIG. 10, this is achieved using a sequence of digital printing procedures. In each subsequent printing procedure of the sequence a selection of dots may be printed over dots printed in previous procedures. In a variation of the described embodiment that dots may also have a composition selected to result in a desired appearance as described above with reference to FIG. 11. Step 1208 then forms a visible layer including an image on the material layer. The visible layer, which would be non-planar if the height differences of the dots were not equalised, is analogous the visible layer 610 discussed with reference to FIG. 6. Step 1210 adheres a glass pane (thickness 3 mm) to the resultant structure using a layer of PVB.

A variation of the method 800 is now described with reference to FIGS. 1 and 2. Initially the visible layer 104 is formed on the adhesive layer 103 of glass panel 102 using the digital printing process as described above. The material layer 106 is then printed on the image layer 102 in the above-described manner. Optionally, a layer of transparent ink or heat-resistant clear varnish 152 (as shown in FIG. 2) is then formed and fills gaps between adjacent dots, equalised height differences between the dots forming a planar surface. Thereafter a conventional thin film solar cell structure 108 is formed either directly on the material layer 106 (FIG. 1) or on the layer of transparent ink or heat-resistant clear varnish (152). A person skilled in the art will appreciated that the formation of such a conventional solar cells structure is well known and will not be described in further detail herein. The glass panel 112 is adhered to the formed structure using the PVB sheet 110.

1. A photovoltaic module having a desired appearance, the module comprising:
at least one solar cell having black or dark surface portions;
a material layer positioned over the black or dark surface portions of the at least one solar cell, the material layer having material portions being lighter in colour or appearance than the black or dark surface portions of the at least one solar cell, the material portions having a transmissivity for visible light dependent on a composition and/or thickness of the material portions, the material layer being at least largely transmissive for light at areas between the material portions; and
a visible layer positioned over the material layer and including at least one of: an image, a pattern or a colour; wherein the thickness, composition and/or lateral coverage of the material portions of the material layer are selected dependent on a desired contrast and/or a darkness, brightness or colour of features of the desired appearance of the photovoltaic module.

2. The photovoltaic module of claim 1 wherein the material layer comprises a plurality of islands provided in the form of dots.

3. The photovoltaic module of claim 2 wherein the dots have a local thickness dependent on desired contrast and/or a darkness or brightness of features of the desired appearance of the photovoltaic module.

4. The photovoltaic module of claim 2 wherein at least some of the dots are sufficiently thin such that the dots have a transmissivity for visible light dependent on the thickness of the dots.

5. The photovoltaic module of claim 2 wherein at least the majority of the dots have a thickness within the range of 0-5 μm and are largely invisible to the naked eye.

6. The photovoltaic module of claim 2 wherein the dots have a composition dependent on desired contrast and/or a darkness or brightness of features of the desired appearance of the photovoltaic module.

7. The photovoltaic module of claim 6 wherein the dots have a transmissivity dependent on the composition of the dots.

8. The photovoltaic module of claim 6 wherein the dots comprise non-transparent ink and a transparent ink or varnish.

9. The photovoltaic module of claim 8 wherein the dots have, dependent on a desired local transmissivity, a composition including 0-20%, 20-40%, 40-60%, 60-80% or 80-100% transparent ink or varnish with the remainder being a non transparent ink whereby a transmissivity of the dots depends on the composition of the dots.

10. The photovoltaic module of claim 2 wherein the dots are formed using a digital printing process.

11. The photovoltaic module of claim 2 wherein the visible layer includes a printed image formed within the visible layer without the use of back colour, even though features of the image as visualised from outside of the photovoltaic module appear black or dark.

12. The photovoltaic module of claim 11 wherein the image is printed using the colours cyan, magenta and yellow only.

13. The photovoltaic module of claim 2 wherein a diameter of the dots of the material layer and distance between the dots determines a coverage of the material layer selected dependent on a desired contrast and/or a darkness or brightness of features of the desired appearance of the photovoltaic module.

14. The photovoltaic module of claim 2 wherein the dots have a diameter of 50 μm-200 μm and gaps between adjacent dots have an extension of 20-40 μm, 40-60 μm, 60-80 μm and 80-100 μm such as 30 μm.

15. The photovoltaic module of claim 2 wherein the thickness and/or composition of the dots of the material layer and properties of the image of the visible layer are selected such that at least the majority or all areas of visible layer and the material layer have a transmissivity for visible light greater than zero.

16. The photovoltaic module of claim 2 wherein the thickness of the dots is reduced to 70% or less,
50% or less, 30% or less, 20% or less even to 10% less of the minimal thickness at which the dots would block transmission of visible light through the dots by more than 90%.

17. The photovoltaic module of claim 2, wherein a composition of the dots is changed by increasing a percentage amount of transparent ink for forming the dots to 30% or more, 50% or more, 70% or more, 80% or more or even 90% or more.

18. The photovoltaic module of claim 2 wherein the at least one solar cell is a cadmium telluride (CdTe)-based solar cell.

19. The photovoltaic module of claim 1, wherein the visible layer is a first visible layer positioned over a first major surface of the at least one solar cell, wherein the photovoltaic module further comprises a second visible layer including at least one of: a colour, an image and a pattern, and wherein the second visible layer is positioned over a second major surface of the at least one solar cell and which is opposite the first major surface such that the first and second visible layers are visible at opposite sides of the at least one solar cell.

20. The photovoltaic module of claim 2 wherein a layer of clear varnish or transparent ink is positioned over the material layer to substantially equalise height differences of the dots and substantially fill gaps between adjacent dots.

21. A method of forming a photovoltaic module having a desired appearance, the method comprising the steps of:
providing at least one solar cell having black or dark surface portions;
forming a material layer over the black or dark surface portions of the at least one solar cell, the material layer having material portions being lighter in colour or appearance than the black or dark surface portions of the at least one solar cell, the material portions having a transmissivity for visible light depending on a thickness and/or composition of the material portions, the material layer being at least largely transmissive for light at areas between the material portions; and
forming a visible layer, the visible layer including at least one of: an image, a pattern or a colour;
wherein the material layer is positioned between the black or dark surface portions of the at least one solar cell and the visible layer, and wherein forming the material layer comprises selecting the thickness, composition and/or lateral coverage of the material portions of the material layer dependent on a desired contrast and/or a darkness, brightness or colour of features of the desired appearance of the photovoltaic module.

22. The method of claim 21 wherein the step of forming the material layer and/or forming the visible layer comprises digital printing, such as digital UV printing or digital ceramic printing.

23. The method of claim 21 wherein the material portions of the material layer are dots.

24. The method of claim 23 wherein the dots have a thickness in the range of 0-10 μm or 0-5 μm.

25. The method of claim 23 wherein the dots have a diameter of 50 μm-200 μm and gaps between adjacent dots have an extension of 20-40 μm, 40-60 μm, 60-80 μm and 80-100 μm such as 30 μm.

26. The method of claim 23 wherein forming the material layer comprises selecting a desired thickness variation of the dots within the material layer.

27. The method of claim 23 wherein forming the material layer comprises a sequence of printing procedures, wherein a selection of dots is printed over dots printed in a previous procedure resulting in an increase in thickness, further comprising selecting for each printing sequence locations at which dots will be printed.

28. The method of claim 23 further comprising applying a layer of transparent ink or varnish in a manner such that the transparent ink or varnish fills gaps between adjacent dots and substantially equalises height differences arising from dots having different thicknesses.

29. The method of claim 23 wherein forming the material layer comprises selecting a composition of the dots and/or a composition variation of the dots within the material layer.

30. The method of claim 29 wherein the dots have a transmissivity dependent on the composition of the dots.

31. The method of claim 30 wherein the dots are formed using a composition of ink transmissive for visible light and ink not transmissive for visible light.

32. The method of claim 31 comprising selecting a ratio of ink or varnish transmissive for visible light and ink not transmissive for visible light.

33. The method of claim 29 further comprising applying a layer of transparent ink or varnish in a manner such that the transparent ink or varnish fills gaps between adjacent dots.

34. The method of claim 21 wherein the step of forming the material layer comprises forming the visible layer directly or indirectly on a surface of a panel transmissive for light.

35. The method of claim 34 comprising forming the material layer directly or indirectly on the visible layer.

36. The method of claim 35 further comprising forming a solar cell structure over the formed material layer.

37. The method of claim 36 further comprising positioning a glass pane over the formed solar cell structure.

38. The method of claim 21 to 29 comprising providing a solar cell structure and forming the material layer directly or indirectly on a surface of the solar cell structure.

39. The method of claim 38 comprising forming the visible layer directly or indirectly on the formed material layer.

40. The method of claim 39 comprising positioning a glass pane over the formed visible layer.
